(19) United States
(12) Patent Application Publication
(10) Pub. No.: US 2020/0091411 A1
(43) Pub. Date: Mar. 19, 2020

(54) MAGNETORESISTIVE MEMORY DEVICE

(71) Applicant: TOSHIBA MEMORY CORPORATION, Tokyo (JP)

(72) Inventor: Yasuyuki SONODA, Seoul (KR)

(73) Assignee: TOSHIBA MEMORY CORPORATION, Tokyo (JP)

(21) Appl. No.: 16/352,547

(22) Filed: Mar. 13, 2019

(30) Foreign Application Priority Data
Sep. 18, 2018 (JP) 2018-174182

(51) Int. Cl. H01L 43/02; H01L 43/12

(52) U.S. Cl. CPC H01L 43/02; H01L 27/228; H01L 43/12

(57) ABSTRACT

According to one embodiment, a magnetoresistive memory device includes: a bottom structure; a layer stack on the bottom structure; a first insulating layer on a sidewall of the layer stack; a first spacer layer on the first insulating layer; a second insulating layer on the first spacer layer; a second spacer layer on the second insulating layer; and a third insulating layer on the second spacer layer. The layer stack includes a first ferromagnetic layer, a second ferromagnetic layer, and a nonmagnetic layer between the first ferromagnetic layer and the second ferromagnetic layer.

### CROSS-REFERENCE TO RELATED APPLICATIONS

This application is based upon and claims the benefit of priority from Japanese Patent Application No. 2018-174182, filed Sep. 18, 2018, the entire contents of which are incorporated herein by reference.

### FIELD

Embodiments described herein relate generally to a magnetoresistive memory device.

### BACKGROUND

A magnetoresistive random access memory (MRAM) is a memory device that includes a storage element having a magnetoresistive effect as a memory cell for storing information. MRAMs have attracted attention as a next generation memory device characterized by high-speed operation, large capacity, and non-volatility.

### BRIEF DESCRIPTION OF THE DRAWINGS

FIG. 1 is a block diagram schematically showing a general arrangement of a magnetoresistive memory device according to an embodiment;

FIG. 2 is a schematic view of a memory cell array in the magnetoresistive memory device according to the embodiment;

FIG. 3 is a cross-sectional view schematically showing an exemplary arrangement of a resistance change element in the magnetoresistive memory device according to the embodiment;

FIG. 4A is a view that shows writing in a magnetoresistive effect element in the magnetoresistive memory device according to the embodiment, showing a schematic cross-section of the magnetoresistive effect element in a parallel state (P state);

FIG. 4B is a view that shows writing in the magnetoresistive effect element in the magnetoresistive memory device according to the embodiment, showing a schematic cross-section of the magnetoresistive effect element in an antiparallel state (AP state);

FIGS. 5, 6, 7, 8, 9, 10, 11, and 12 are a cross-sectional views schematically showing an exemplary manufacturing process of the resistance change element according to the embodiment; and

FIG. 13 is a cross-sectional view for schematically showing a structure of a resistance change element according to a comparative example.

### DETAILED DESCRIPTION

According to one embodiment, a magnetoresistive memory device includes: a bottom structure; a layer stack on the bottom structure; a first insulating layer on a sidewall of the layer stack; a first spacer layer on the first insulating layer; a second insulating layer on the first spacer layer; a second spacer layer on the second insulating layer; and a third insulating layer on the second spacer layer. The layer stack includes a first ferromagnetic layer, a second ferromagnetic layer, and a nonmagnetic layer between the first ferromagnetic layer and the second ferromagnetic layer.

An embodiment will hereinafter be described with reference to the drawings. In the drawings, the same components are denoted by the same reference numerals. In the following description, the term “connect” includes not only “to connect directly” but also “to connect through any elements” unless otherwise specified. Furthermore, a first terminal of a transistor represents one of a source or a drain, and a second terminal of the transistor represents the other of the source or the drain. A control terminal of the transistor represents a gate.

A magnetoresistive memory device according to the embodiment is, for example, a magnetoresistive random access memory (MRAM) including a magnetic tunnel junction (MTJ) element as a storage element. The embodiment will hereinafter be described based on the example where the magnetoresistive memory device is a MRAM.

### Example of Arrangement

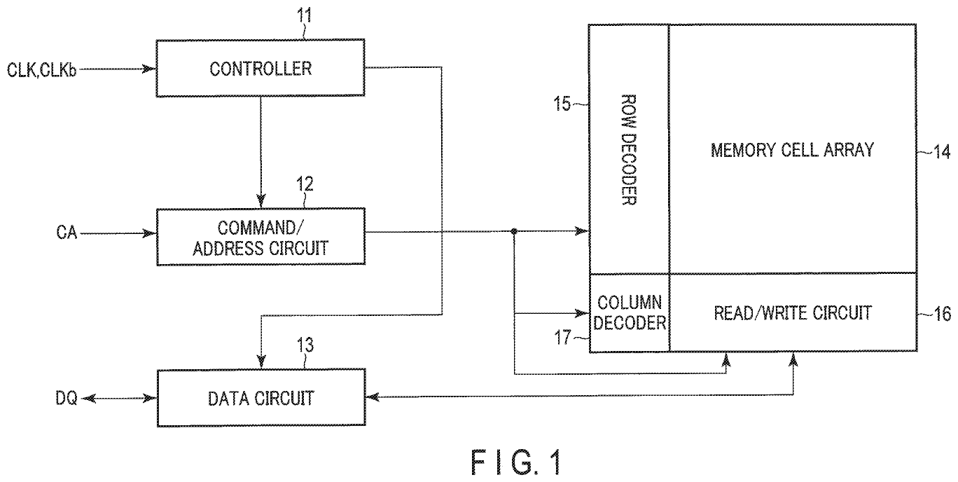

FIG. 1 is a block diagram showing a general arrangement of the magnetoresistive memory device according to the embodiment.

As shown in FIG. 1, the magnetoresistive memory device includes a controller 11, a command/address circuit 12, a data circuit 13, a memory cell array 14, a row decoder 15, a read/write circuit 16, and a column decoder 17.

The controller 11 receives clock signals CLK and CLKb and an external control signal from the outside of the magnetoresistive memory device, for example, from a host device. The controller 11 includes components such as a voltage generator and controls the command/address circuit 12 and the data circuit 13 based on the control signal from the outside.

The command/address circuit 12 receives a command/address signal CA from the outside. The command/address circuit 12 supplies signals based on the received signals to the row decoder 15, the read/write circuit 16, and the column decoder 17.

The data circuit 13 performs transmission and reception of data DQ between the outside and the read/write circuit 16. More specifically, the data circuit 13 transfers write data from the outside to the read/write circuit 16. The data circuit 13 transfers read data from the read/write circuit 16 to the outside.

The row decoder 15 receives a row address from the command/address circuit 12 and selects a word line WL according to the received row address. The column decoder 17 receives a column address from the command/address circuit 12 and selects a bit line BL and a source line SL according to the received column address. The read/write circuit 16 includes, for example, a sense amplifier and controls writing and reading with respect to the memory cell array 14.

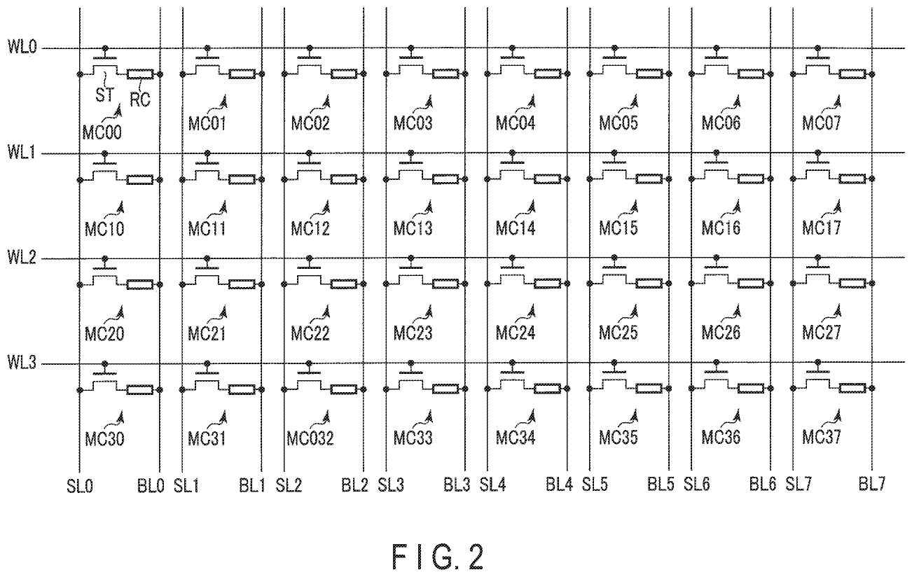

FIG. 2 is a view of the memory cell array 14 in the magnetoresistive memory device according to the embodiment. As shown in FIG. 2, bit lines BL (BL0 to BL7), source lines SL (SL0 to SL7), and word lines WL (WL0 to WL3) are provided in the memory cell array 14. The bit lines BL and the source lines SL extend in a first direction. The bit lines BL and the source lines SL are provided alternately in a second direction which is perpendicular to the first direction. The word lines WL extend in the second direction. The memory cell array 14 includes memory cells MC (MC00 to MC07, MC10 to MC17, MC20 to MC27, and MC30 to MC37). Each memory cell MC is provided at an intersection between each of the bit lines BL and the source lines SL and each of the word lines WL. In other words, the memory cells MC are arranged in a matrix in the first direction and the second direction.

More specifically, the memory cells MC00 to MC07 are provided at intersections between the bit lines BL0 to BL7 and the source lines SL0 to SL7 and the word line WL0. The memory cells MC10 to MC17 are provided at intersections between the bit lines BL0 to BL7 and the source lines SL0 to SL7 and the word line WL1. The memory cells MC20 to MC27 are provided at intersections between the bit lines BL0 to BL7 and the source lines SL0 to SL7 and the word line WL2. The memory cells MC30 to MC37 are provided at intersections between the bit lines BL0 to BL7 and the source lines SL0 to SL7 and the word line WL3. Each memory cell MC is electrically connected to a bit line BL, a source line SL, and a word line WL at the intersection.

It should be noted the number of the bit lines BL, the source lines SL, and the word lines WL of the memory cell array 14 herein is for purposes of illustration and not limitation.

Each memory cell MC includes, for example, a resistance change element RC and a select transistor ST. A first terminal of the resistance change element RC is electrically connected to a corresponding bit line BL. A second terminal of the resistance change element RC is electrically connected to the first terminal of the select transistor ST. The second terminal of the select transistor ST is electrically connected to a corresponding source line SL. A control terminal of the select transistor ST is electrically connected to a corresponding word line WL. Each memory cell MC is selected, when the select transistor ST is turned on by the word line WL. When a current (or a voltage) is applied to the resistance change element RC, the resistance change element RC changes a resistance. The resistance change element RC includes, for example, an MTJ element. Hereinafter described is an example where the resistance change element RC is an MTJ element.

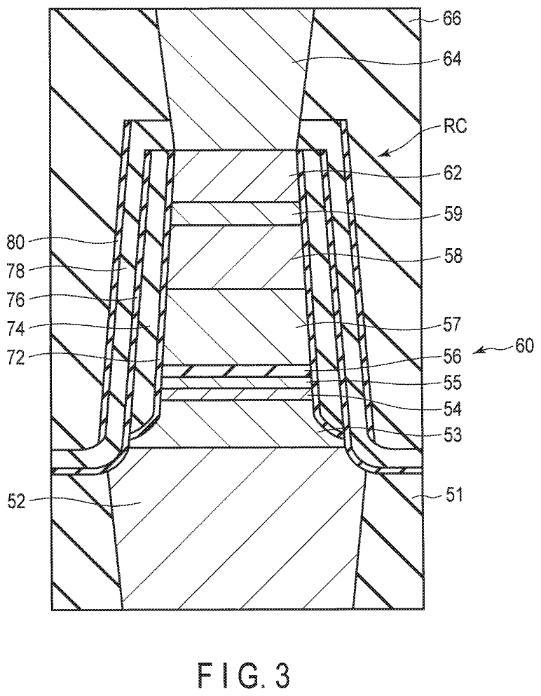

FIG. 3 is a cross-sectional view of the resistance change element RC according to the embodiment. Hereinafter, for convenience sake, a direction from a bottom electrode 52 to a top electrode 64 in a stack direction (vertical direction in FIG. 3) is referred to as “upper side”, and the opposite direction is referred to as “lower side”. However, this notation is for the purpose of convenience and is irrelevant to the direction of gravity.

The bottom electrode 52 is provided in a contact hole of a bottom insulating layer 51. The bottom electrode 52 extends in the stack direction (vertical direction in FIG. 3) inside the bottom insulating layer 51. A lower end of the bottom electrode 52 is connected to a drain electrode of the select transistor ST. The bottom electrode 52 contains a hardly-oxidizable metal. The bottom electrode 52 may contain, for example, at least one of W, Ta, Ru, Ti, TaN, and TiN.

A buffer layer 53 is provided on a part of an upper end of the bottom electrode 52. The buffer layer 53 is a metal layer and is an easily-oxidizable metal which is more easily oxidized than the bottom electrode 52. The buffer layer 53 contains, for example, at least one of Al, Be, Mg, Ca, Hf, Sr, Ba, Sc, Y, La, and Zr. The buffer layer 53 may also include at least one of compounds such as HfB, MgAlB, HfAlB, ScAlB, ScHfB, and HfMgB.

The hardly-oxidizable metal and the easily-oxidizable metal can be determined, for example, by a standard electrode potential. Specifically, when a standard electrode potential of a first metal included in the buffer layer 53 is lower than a standard electrode potential of a second metal included in the bottom electrode 52, the first metal of the buffer layer 53 can be defined as an easily-oxidizable metal, and the second metal of the bottom electrode 52 can be defined as a hardly-oxidizable metal.

On the buffer layer 53, an underlayer 54 is provided. On the underlayer 54, an MTJ element 60 is provided as described later. The underlayer 54 is provided, for example, to facilitate crystallization of the MTJ element 60. The underlayer 54 may include at least one of metal compounds contained in the buffer layer 53, such as HfB, MgAlB, HfAlB, ScAlB, ScHfB, and HfMgB. In a case where the MTJ element 60 is sufficiently crystalized without the underlayer 54, the underlayer 54 may be omitted.

As described above, the MTJ element 60 is provided on the underlayer 54. The MTJ element 60 includes a storage layer 55, a tunnel barrier layer 56, and a reference layer 57, which are disposed in this order from the underlayer 54. The storage layer 55 is a ferromagnetic magnetization free layer and includes, for example, CoFeB, FeB, or MgFeO. The tunnel barrier layer 56 is a nonmagnetic layer and includes, for example, MgO or AlO. The tunnel barrier layer 56 may also include a nitride of element such as Al, Si, Be, Mg, Ca, Sr, Ba, Sc, Y, La, Zr, or Hf. The reference layer 57 is a ferromagnetic magnetization fixed layer and includes, for example, CoFeB, FeB, or MgFeO. In other words, the MTJ element 60 has a structure in which the nonmagnetic layer (tunnel barrier layer 56) is sandwiched between two ferromagnetic layers (the storage layer 55 and the reference layer 57).

On the MTJ element 60, a shift cancel layer 58 is provided. The shift cancel layer 58 includes, for example, Co and at least one element selected from Pt, Ni, and Pd.

On the shift cancel layer 58, a capping layer 59 is provided. The capping layer 59 is a metal layer and includes, for example, at least one of Ta, Ru, Pt, and W.

A hard mask 62 of a metal layer is provided on the capping layer 59. The hard mask 62 functions as a mask while the resistance change element RC is being patterned.

A sidewall (side surface) of the resistance change element RC, which includes the buffer layer 53, the underlayer 54, the MTJ element 60, the shift cancel layer 58, the capping layer 59, and the hard mask 62, is provided with a first redeposition layer 72, a first spacer layer 74, a second redeposition layer 76, a second spacer layer 78, and a sidewall insulating layer 80. The first redeposition layer 72 and the second redeposition layer 76 also function as sidewall insulating layers.

An insulating layer 66 is provided so as to cover the bottom insulating layer 51 and the resistance change element RC. The insulating layer 66 is, for example, a silicon nitride layer or a silicon oxide layer.

The top electrode 64 is provided in a contact hole in the insulating layer 66. The top electrode 64 extends in the stack direction inside the insulating layer 66. A lower end of the top electrode 64 is connected to the hard mask 62. The top electrode 64 is a metal layer including a metal and includes, for example, at least one of W, Ta, Ru, Ti, TaN, and TiN.

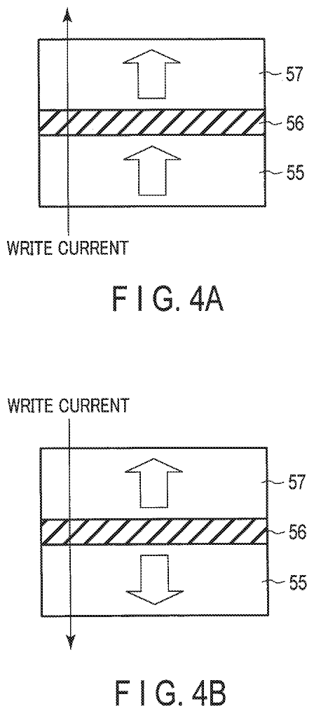

FIGS. 4A and 4B are schematic cross-sectional views of the MTJ element 60 in the magnetoresistive memory device according to the embodiment. FIG. 4A is a view that shows writing in the MTJ element 60 in the magnetoresistive memory device according to the embodiment, showing a schematic cross-section of the MTJ element 60 in a parallel state (P state). FIG. 4B is a view that shows writing in the MTJ element 60 in the magnetoresistive memory device according to the embodiment, showing a schematic cross-section of the MTJ element 60 in an antiparallel state (AP state).

As shown in FIGS. 4A and 4B, the storage layer 55 is a ferromagnetic layer whose magnetization direction is variable and has, for example, perpendicular magnetic anisotropy perpendicular or substantially perpendicular to a film surface (upper surface/lower surface). Herein, the expression “magnetization direction is variable” indicates that the magnetization direction changes in response to a predetermined write current. The term “substantially perpendicular” indicates that the direction of residual magnetization is within a range of 45°<8 90° relative to the film surface.

The reference layer 57 is a ferromagnetic layer whose magnetization direction is invariant and has perpendicular magnetic anisotropy perpendicular or substantially perpendicular to the film surface. Herein, the expression “magnetization direction is invariant” indicates that the magnetization direction does not change in response to a predetermined write current. In other words, inversion energy barrier in the magnetization direction is larger in the reference layer 57 than the storage layer 55.

In this example, the MTJ element 60 is, for example, a resistance change element of a spin injection type. Accordingly, when data is written into the MTJ element 60 or when data is read from the MTJ element 60, a current may flow in the MTJ element 60 in both directions perpendicular to the film surface. More specifically, data is written into the MTJ element 60 by the following manner.

As shown in FIG. 4A, when a current flows from the storage layer 55 to the reference layer 57, that is, when electrons are supplied from the reference layer 57 to the storage layer 55, electrons spin-polarized in the same direction as the magnetization direction of the reference layer 57 are injected into the storage layer 55. In this case, the magnetization direction of the storage layer 55 comes to be aligned in the same direction as the magnetization direction of the reference layer 57. Accordingly, the magnetization direction of the reference layer 57 and that of the storage layer 55 are arranged in parallel. In this parallel state, the MTJ element 60 has a lower one of two resistances or a minimum resistance. This state is defined, for example, as “0” data.

On the other hand, as shown in FIG. 4B, when a current flows from the reference layer 57 to the storage layer 55, that is, when electrons are supplied from the storage layer 55 to the reference layer 57, the electrons are reflected by the reference layer 57, which causes electrons spin-polarized in the direction opposite to the magnetization direction of the reference layer 57 to be injected into the storage layer 55. In this case, the magnetization direction of the storage layer 55 comes to be aligned in the direction opposite to the magnetization direction of the reference layer 57. Accordingly, the magnetization direction of the reference layer 57 and that of the storage layer 55 are arranged in antiparallel. In this antiparallel state, the MTJ element 60 has a higher one of the two resistances or a maximum resistance. This state is defined, for example, as “1” data.

The data is read from the MTJ element 60 in the following manner. A read current is supplied to the MTJ element 60. The read current is set to have a magnitude which does not reverse the magnetization direction of the storage layer 55, or a magnitude smaller than the write current. By detecting a resistance of the MTJ element 60 at this time, the “0” data and the “1” data can be read.

### Example of Manufacturing Method

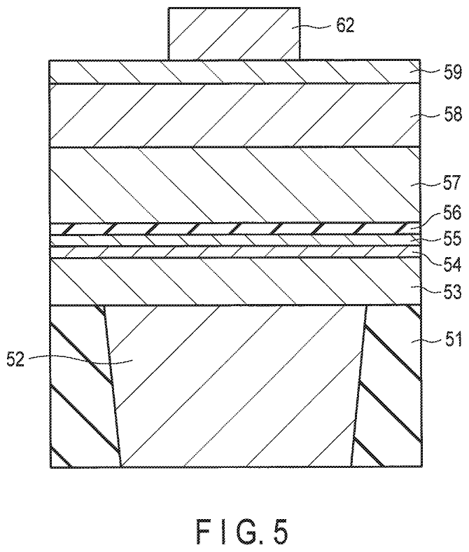

FIGS. 5 to 12 are cross-sectional views showing an exemplary manufacturing process of the resistance change element RC in the magnetoresistive memory device according to the embodiment.

As shown in FIG. 5, the buffer layer 53 and the underlayer 54 are formed in order on the bottom electrode 52 and the bottom insulating layer 51 by, for example, sputtering or chemical vapor deposition (CVD). Next, the storage layer 55, the tunnel barrier layer 56, the reference layer 57, the shift cancel layer 58, and the capping layer 59 are formed in order on the underlayer 54 by, for example, sputtering. Subsequently, the hard mask 62 is formed on the capping layer 59 by lithography and etching process. The hard mask 62 is patterned so that the hard mask 62 corresponds to a pattern of the resistance change element RC. In other words, the hard mask 62 is formed so as to correspond to an area above the bottom electrode 52. The hard mask 62 is a metal layer.

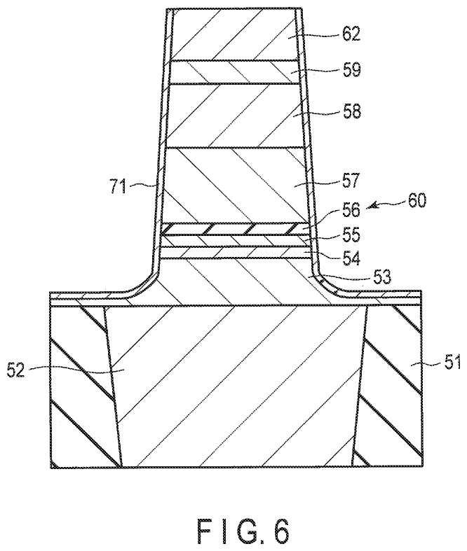

Next, as shown in FIG. 6, first etching is performed. The first etching is performed by physical etching such as ion beam etching (IBE). An inert gas used for an ion beam in the IBE is, for example, Ar, Xe, Kr, or Ne. In the first etching, an area from the capping layer 59 to the middle of the buffer layer 53 is etched with the hard mask 62. That is, the capping layer 59, the shift cancel layer 58, the MTJ element 60, the underlayer 54, and part of the buffer layer 53 are etched.

Description will be given of the reason why the first etching is stopped in the middle of the buffer layer 53. Generally, with IBE, a material from a to-be-etched layer is redeposited to a sidewall of a resistance change element RC. The etching is carried out while a redeposition layer formed by redeposition is also removed by IBE, but it is difficult to completely remove redeposits derived from the bottommost metal layer which is etched last. Accordingly, for example, if the first etching is performed till the bottom electrode 52 containing a hardly-oxidizable metal is etched, the hardly-oxidizable metal is redeposited on the sidewall of the resistance change element RC. It is difficult to oxidize and completely insulate the redeposition layer that contains the hardly-oxidizable metal. Due to the redeposited hardly-oxidizable metal, the storage layer 55 and the reference layer 57 may be short-circuited, which may cause a failure. Thus, in this embodiment, the first etching is stopped at the buffer layer 53 that contains the easily-oxidizable metal. Accordingly, in the first etching, a redeposition layer 71 including the easily-oxidizable metal contained in the buffer layer 53 is formed on the sidewall of the resistance change element RC, and a redeposition layer including the hardly-oxidizable metal contained in the bottom electrode 52 is not formed thereon.

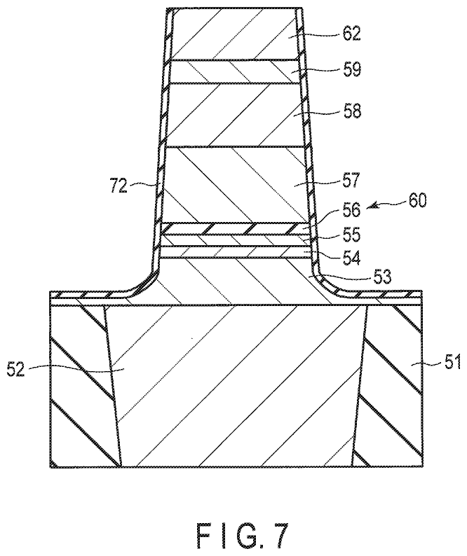

After the first etching, the redeposition layer 71 including the easily-oxidizable metal is converted into an oxide by oxidation such as thermal oxidation. This results in the first redeposition layer 72 that contains the oxide of the easily-oxidizable metal formed on the sidewall of the resistance change element RC as shown in FIG. 7. The redeposition layer 71 including the easily-oxidizable metal can be wholly converted into the first redeposition layer 72. This suppresses or prevents a short circuit between the storage layer 55 and the reference layer 57 due to the first redeposition layer 72. The first redeposition layer 72 has a thickness of, for example, about 1 nm.

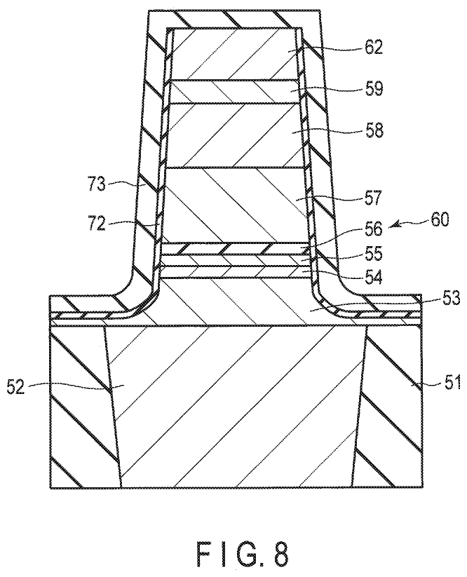

As shown in FIG. 8, an insulating layer 73 is formed by CVD or the like. The insulating layer 73 includes silicon nitride, silicon oxide, or the like, and a part of the insulating layer 73 serves as the first spacer layer 74.

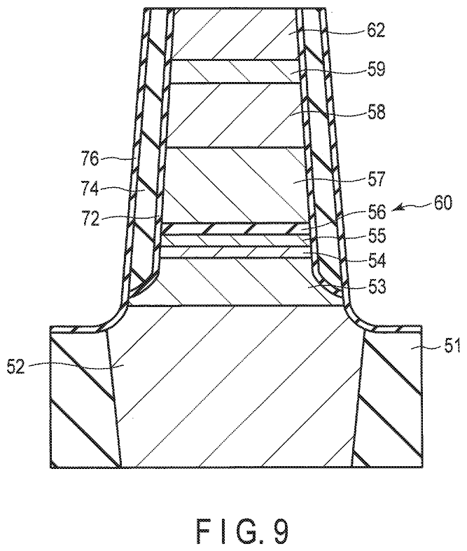

As shown in FIG. 9, second etching is performed. Similarly to the first etching, the second etching is carried out by physical etching such as IBE. In the second etching, the insulating layer 73, the first redeposition layer 72, the buffer layer 53, the bottom electrode 52, and the bottom insulating layer 51 are etched with the hard mask 62. The second etching is carried out in order to electrically separate the resistance change elements RC from each other. In other words, etching of the first redeposition layer 72 and the buffer layer 53 electrically separates the resistance change elements RC in the memory cell array 14.

The second etching forms the first spacer layer 74 that covers the first redeposition layer 72. At this time, a redeposition layer derived from the last etched bottom electrode 52 is formed on the sidewall of the resistance change element RC. Then, the redeposited material is oxidized to form the second redeposition layer 76. The second redeposition layer 76 is not directly in contact with the sidewall of the MTJ element 60, which suppresses or prevents a short circuit between the storage layer 55 and the reference layer 57 due to the second redeposition layer 76. The first spacer layer 74 has a thickness of about 1 to 5 nm, or, for example, about 3 nm. The second redeposition layer 76 has a thickness of, for example, about 1 nm.

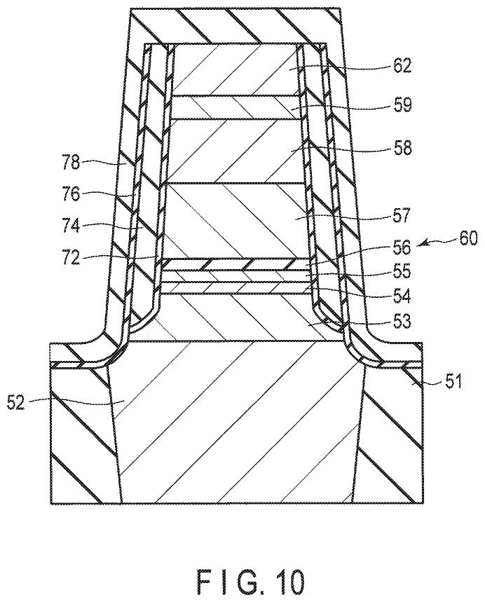

As shown in FIG. 10, the second spacer layer 78 that covers the second redeposition layer 76 is formed by CVD or the like. The second spacer layer 78 includes silicon nitride, silicon oxide, or the like. The second spacer layer 78 has a thickness of about 1 to 5 nm, or, for example, about 3 nm.

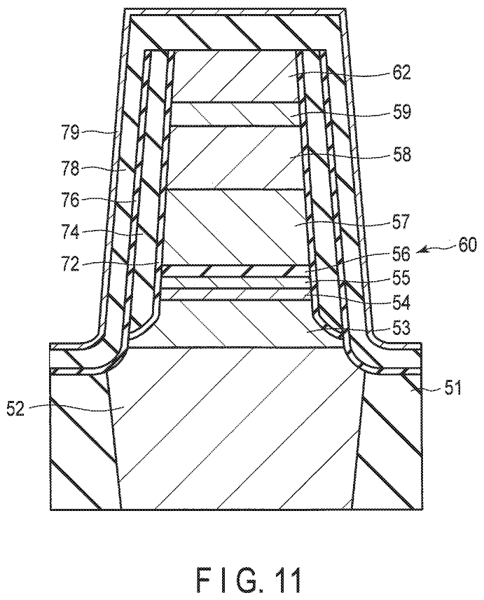

As shown in FIG. 11, a thin film 79 that covers the second spacer layer 78 is formed by CVD or the like. The thin film 79 may include a metal similar to that of the buffer layer 53. Specifically, the thin film 79 may include, for example, at least one of Al, Be, Mg, Ca, Hf, Sr, Ba, Sc, Y, La, and Zr. The thin film 79 may also include at least one of compounds such as HfB, MgAlB, HfAlB, ScAlB, ScHfB, and HfMgB.

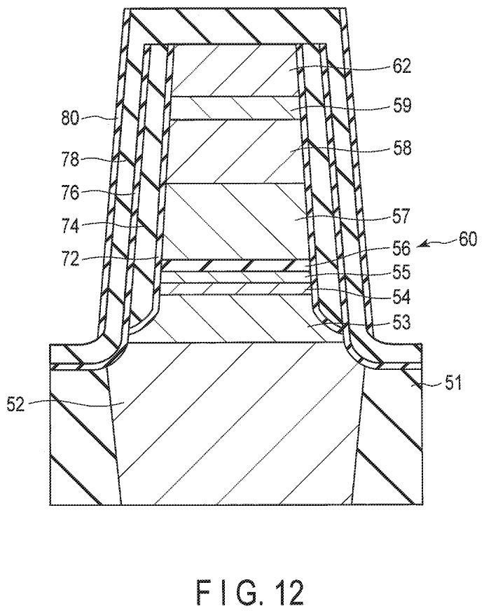

As shown in FIG. 12, third etching is performed. Similarly to the first etching and the second etching, the third etching is carried out by physical etching such as IBE. In the third etching, the thin film 79 is etched. The third etching is performed to remove a top portion of the thin film 79, i.e., a part above the hard mask 62 of the thin film 79. At this time, material etched away from a portion of the thin film 79 above the bottom insulating layer 51 is redposited on other parts of the thin film 79. As a result, a redeposition layer derived from the etched thin film 79 is formed on the sidewall of the resistance change element RC, particularly on the bottom part, whereby forming the sidewall insulating layer 80. In a case where the thin film 79 is a metal film, oxidation is performed afterward so as to form the metal oxide sidewall insulating layer 80. The sidewall insulating layer 80 has a thickness of, for example, about 1 nm.

After that, as shown in FIG. 1, the insulating layer 66 is formed to cover the entire resistance change element RC, and a contact hole where the top electrode 64 is to be provided is formed in the insulating layer 66, and then, the top electrode 64 is formed in the contact hole. Through the process, the resistance change element RC as shown in FIG. 3 is formed.

Note that the third etching may be omitted. However, when reactive ion etching (RIE) is employed to form the contact hole for the top electrode 64, it is necessary that the silicon nitride second spacer layer 78 of the thin film 79 should have no upper portion and be exposed. Accordingly, when RIE is employed for forming the contact hole, it is preferable to perform the third etching by IBE.

[Comparison with Another Structure]

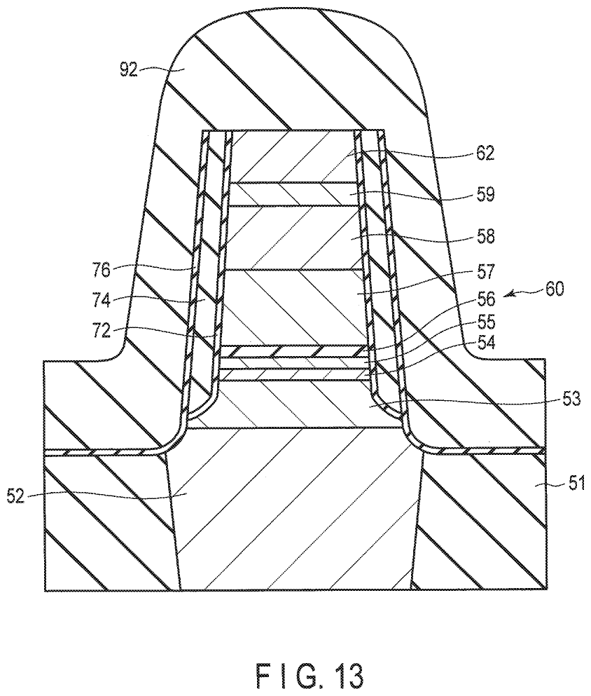

The structure according to this embodiment is compared with another structure. An example of another structure is shown in FIG. 13. In this structure, a silicon nitride film 92 is formed after the second redeposition layer 76 shown in FIG. 9 is formed in the embodiment.

The silicon nitride film 92 serves as a protective film while an insulating film such as the insulating layer 66 is being formed later by high density plasma (HDP) CVD.

The embodiment's three insulating layers on the sidewall of the resistance change element RC: the first redeposition layer 72, the second redeposition layer 76, and the sidewall insulating layer 80, can be a substitute for the silicon nitride film 92 in the structure shown in FIG. 13. The silicon nitride film 92 shown in FIG. 13 has a thickness of, for example, about 20 nm, whereas each spacer layer according to this embodiment may only need to have a thickness of, for example, about 3 to 5 nm. Therefore, even though multiple spacer layers are provided in the structure, the set of the spacer layers can be thinner than the silicon nitride film 92 shown in FIG. 13. Thinning the sidewall of the resistance change element RC also contributes to an increase in density of the resistance change element RC.

### Modification

In the embodiment, the single-layer sidewall insulating layer 80 is provided outside the second spacer layer 78. However, more spacer layers and sidewall insulating layers, for example, a third spacer layer and a second sidewall insulating layer, may be provided repeatedly on the sidewall insulating layer 80. With such an arrangement, it is expected to further suppress the deterioration of magnetic properties of an MTJ device which results from the protection function of a sidewall insulating film.

The embodiment illustrates the resistance change element RC including the MTJ element 60 of what is called a top-pin type in which the storage layer 55 is provided below the tunnel barrier layer 56 and the reference layer 57 is provided above the tunnel barrier layer 56. However, the embodiment is not limited to this example. The resistance change element RC may include an MTJ element of what is called a bottom-pin type in which a storage layer is provided above a tunnel barrier layer and a reference layer is provided below the tunnel barrier layer.

The embodiment illustrates the MTJ element 60 of a perpendicular magnetization type, but embodiments are not limited thereto. The MTJ element may be of an in-plane magnetization type.

Furthermore, in the described embodiment, the select transistor ST of the three-terminal switching element (selection element) as in FIG. 2 is illustrated as the switching element of the memory cell MC. However, the embodiment may employ a circuit including the following two-terminal switching element.

In other words, the select transistor ST may be, for example, a switching element with two terminals. For example, when a voltage applied between the two terminals is equal to or less than a certain threshold, the switching element is in a “high resistance” state, for example, electrically nonconductive state. When a voltage applied between the two terminals is equal to or higher than a certain threshold, the switching element changes to a “low resistance” state, for example, electrically conductive state. The switching element may have this function regardless of polarity of a voltage.

In this example, the switching element may contain at least one chalcogen element selected from the group consisting of tellurium (Te), selenium (Se), and sulfur (S). Alternatively, the switching element may contain a chalcogenide, a compound containing the chalcogen element. In addition to this element, the switching element may also contain at least one element selected from the group consisting of boron (B), aluminum (Al), gallium (Ga), indium (In), carbon (C), silicon (Si), germanium (Ge), tin (Sn), arsenic (As), phosphorus (P), and antimony (Sb).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive memory device comprising:
a bottom structure;
a layer stack on the bottom structure, the layer stack including a first ferromagnetic layer, a second ferromagnetic layer, and a nonmagnetic layer between the first ferromagnetic layer and the second ferromagnetic layer;
a first insulating layer on a sidewall of the layer stack;
a first spacer layer on the first insulating layer;
a second insulating layer on the first spacer layer;
a second spacer layer on the second insulating layer; and
a third insulating layer on the second spacer layer.

2. The device according to claim 1, wherein:
the third insulating layer includes an oxidized metal.

3. The device according to claim 2, wherein:
the first insulating layer and the second insulating layer include an oxidized metal.

4. The device according to claim 1, wherein:
the first spacer layer and the second spacer layer include silicon nitride or silicon oxide.

5. The device according to claim 1, wherein:
the second insulating layer includes a hardly-oxidizable metal.

6. The device according to claim 1, wherein:
the bottom structure includes a first layer including an easily-oxidizable metal and a second layer including a hardly-oxidizable metal, the first layer and the second layer layer being disposed in order from the layer stack, and
the first insulating layer has a lower end higher than a lower surface of the first layer.

7. The device according to claim 6, wherein:
the second insulating layer has a lower end lower than an upper surface of the second layer.

8. The device according to claim 1, wherein:
the second spacer layer has a thickness of 1 to 5 nm.

9. The device according to claim 1, wherein:
the first spacer layer has a thickness of 1 to 5 nm.

10. The device according to claim 1, further comprising:
a third spacer layer on the third insulating layer; and
a fourth insulating layer on the third spacer layer.

11. A method of manufacturing a magnetoresistive memory device comprising:
forming a second conductive layer on a first conductive layer;
forming a first layer stack on the second conductive layer, the layer stack including a ferromagnetic layer;
performing a first etching to the first layer stack to form a second layer stack, the first etching not etching the first conductive layer;
forming a first insulating layer on a side surface of the second layer stack;
forming a first spacer layer on the first insulating layer;
etching the second conductive layer to remove the second conductive layer in part from an upper surface of the second conductive layer to a lower surface of the second conductive layer;
forming a second insulating layer on the first spacer layer;
forming a second spacer layer on the second insulating layer;
forming a third insulating layer on the second spacer.

12. The method according to claim 11, wherein:
the forming of the third insulating layer includes:
forming a first layer on the second spacer layer; and
etching the first layer in part with ion beam to deposit on the first layer a material removed from another part of the first layer by etching.

13. The method according to claim 12, wherein:
the forming of the second spacer layer includes forming a first part of the second spacer on a third conductive layer above the second layer stack,
the forming of the first layer includes forming a second part of the first layer on the first part of the second spacer layer, and
the etching of the first layer in part includes etching the second part of the first layer.

14. The method according to claim 11, wherein:
the third insulating layer includes an oxidized metal.

15. The method according to claim 14, wherein:
the first insulating layer and the second insulating layer include an oxidized metal.

16. The method according to claim 11, wherein:
the second spacer layer has a thickness of 1 to 5 nm.

17. The method according to claim 16, wherein:
the first spacer layer has a thickness of 1 to 5 nm.

18. The method according to claim 11, wherein:
the first etching forms a first layer on a side surface of the second layer stack, and
the forming of the first insulating layer includes oxidizing the first layer.

19. The method according to claim 18, wherein:
the etching of the second conductive layer forms a second layer on the first spacer,
the forming of the second insulating layer includes oxidizing the second layer.
